(19) United States
(12) Patent Application Publication
(10) Pub. No.: US 2015/0068707 A1
(43) Pub. Date: Mar. 12, 2015

(54) ELECTRONIC COMPONENT COOLING APPARATUS

(71) Applicant: NEC CORPORATION, Tokyo (JP)

(72) Inventor: Hiroyuki HAMAGUCHI, Tokyo (JP)

(21) Appl. No.: 14/480,963

(22) Filed: Sep. 9, 2014

(30) Foreign Application Priority Data
Sep. 9, 2013 (JP) 2013-186248

(51) Int. Cl. H05K 7/20

(52) U.S. Cl. CPC H05K 7/20254
USPC 165/96

(57) ABSTRACT

Provided is an inexpensive and highly reliable electronic component cooling apparatus that includes a pressure increase reduction function of a refrigerant such as water. The electronic component cooling apparatus of the present invention includes a cooling unit having a flow path through which a refrigerant flows, an opening/closing unit included in the flow path for confining the refrigerant, and a pressure reduction unit disposed in at least a part of an inner wall of the flow path.

This application is based upon and claims the benefit of priority from Japanese Patent Application No. 2013-186248, filed on Sep. 9, 2013, the disclosure of which is incorporated herein in its entirety by reference.

### TECHNICAL FIELD

The present invention relates to a cooling apparatus for cooling an electronic component such as a semiconductor component that generates heat.

### BACKGROUND ART

With the recent increase of the amount of heat generated from a semiconductor component such as large scale integration (LSI), cases of adopting a cooling system using a refrigerant such as water have increased. In a typical cooling apparatus, a cold plate is brought into contact with a semiconductor component to absorb heat, and the heat is transferred by a refrigerant such as water passing through the cold plate via piping.

FIG. 8 illustrates a cooling apparatus that includes a cold plate 201, piping 202, couplers 204 for coupling with external piping, and a coupler fixing block 203 for fixing the couplers 204. According to this cooling apparatus, in a state where a refrigerant in the cooling apparatus is separated from a flow path of an external refrigerant by the couplers 204, the refrigerant is confined in the cold plate 201, the piping 202, the coupler fixing block 203, and the couplers 204 that constitute a flow path of the refrigerant in the cooling apparatus. At this time, when a temperature of the refrigerant increases due to an increase of an ambient temperature or the like, pressure in the flow path rapidly increases because the refrigerant such as water is not compressed to be deformed. Consequently, a defect such as breakage of the couplers 204 occurs.

As countermeasures against the defect, for example, Japanese Laid-open Patent Publication No. 2006-59903 discloses a refrigerant system provided with a tank including an air layer or a pressure regulating valve for releasing pressure when fixed pressure is applied.

FIG. 9 illustrates a sectional structure of a cooling apparatus with a pressure reduction tank 206 added to the cooling apparatus illustrated in FIG. 8, from the view taken along the line D-D′ in FIG. 8 . The pressure reduction tank 206 includes an air layer 207 therein. When the refrigerant expands due to a temperature increase or the like to enter into the tank, pressure is reduced by the air layer 207. FIG. 10 illustrates a sectional structure of a cooling apparatus with a pressure regulating valve 208 from the view taken along the line D-D′ in FIG. 8. The pressure regulating valve 208 functions to reduce pressure increase of the refrigerant.

However, installation of the pressure reduction tank 206 illustrated in FIG. 9 causes projection of a tank unit from the cooling apparatus. As a result, an outer shape of the apparatus is enlarged to cause a problem such as interference with installation of the apparatus. In addition, air of the air layer 207 in the tank gradually blends into the refrigerant such as water to cause a problem such as reduction of an effect over a long term. On the other hand, when the pressure regulating valve 208 illustrated in FIG. 10 is installed, a failure may not be avoided because the pressure regulating valve 208 operates mechanically. When there is a failure in the pressure regulating valve 208, the refrigerant such as water may leak to seriously affect a semiconductor component.

### SUMMARY

The present invention has been developed in view of the aforementioned problems, and the object of the invention is to provide an inexpensive and highly reliable electronic component cooling apparatus that includes a pressure increase reduction function of a refrigerant such as water.

According to the present invention, a cooling apparatus includes cooling unit including a flow path through which a refrigerant flows, opening/closing unit included in the flow path for confining the refrigerant, and pressure reduction unit disposed in at least a part of an inner wall of the flow path.

According to the present invention, it is possible to provide an inexpensive and highly reliable electronic component cooling apparatus that includes a pressure increase reduction function of a refrigerant such as water.

### BRIEF DESCRIPTION OF THE DRAWINGS

Exemplary features and advantages of the present invention will become apparent from the following detailed description when taken with the accompanying drawings in which:

FIG. 1 is a diagram illustrating a structure of an electronic component cooling apparatus according to an exemplary embodiment of the present invention;

FIG. 2 is a diagram illustrating a specific structure of the electronic component cooling apparatus according to the exemplary embodiment of the present invention;

FIG. 3 is a diagram illustrating a sectional structure of the electronic component cooling apparatus according to the exemplary embodiment of the present invention;

FIG. 4 is a diagram illustrating a sectional structure of the electronic component cooling apparatus according to the exemplary embodiment of the present invention;

FIG. 5 is a diagram illustrating a sectional structure of the electronic component cooling apparatus according to the exemplary embodiment of the present invention;

FIG. 6 is a diagram illustrating a sectional structure of the electronic component cooling apparatus according to the exemplary embodiment of the present invention;

FIG. 7 is a diagram illustrating a sectional structure of the electronic component cooling apparatus according to the exemplary embodiment of the present invention;

FIG. 8 is a diagram illustrating a structure of an existing electronic component cooling apparatus;

FIG. 9 is a diagram illustrating a sectional structure of the existing electronic component cooling apparatus that includes a pressure reduction tank; and

FIG. 10 is a diagram illustrating a sectional structure of the existing electronic component cooling apparatus that includes a pressure regulating valve.

### EXEMPLARY EMBODIMENT

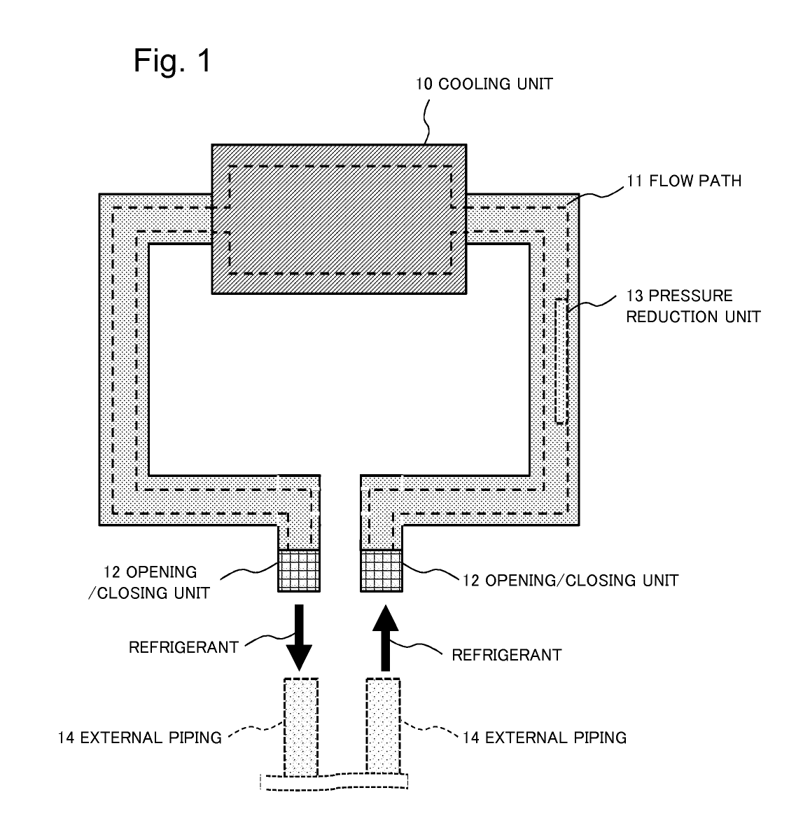

Next, the exemplary embodiment of the present invention will be described in detail with reference to the accompanying drawings. FIG. 1 is a diagram illustrating a structure of an electronic component cooling apparatus according to the exemplary embodiment of the present invention. The cooling apparatus is provided with cooling unit 10 including a flow path 11 through which a refrigerant flows and configured to cool an electronic component, opening/closing unit 12 included in the flow path 11 for confining the refrigerant, and pressure reduction unit 13 disposed in at least a part of an inner wall of the flow path 11. The refrigerant is supplied from external piping 14, and discharged to the external piping 14.

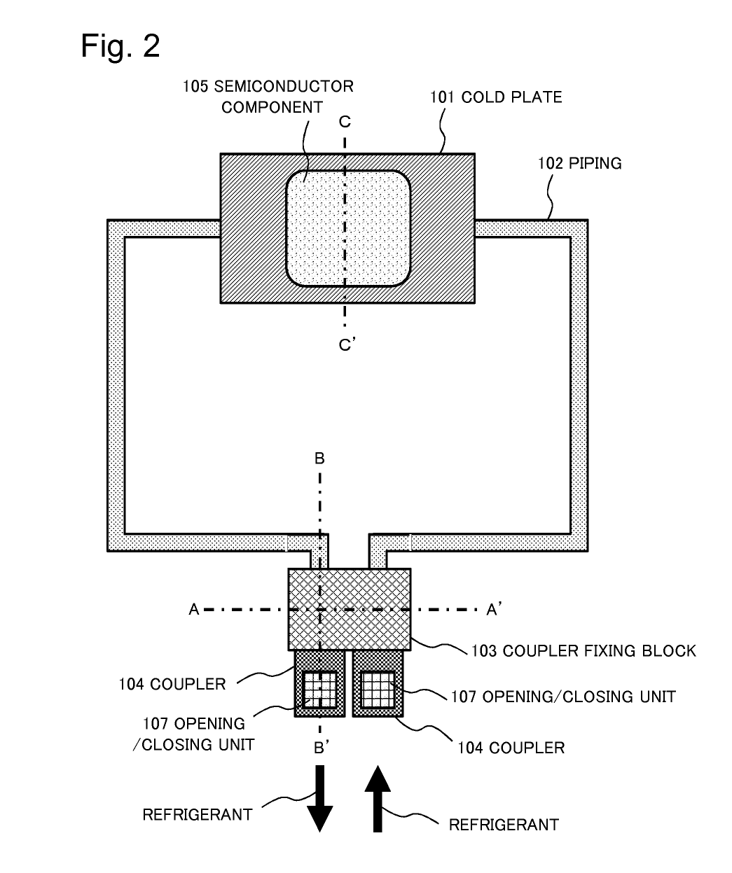

FIG. 2 is a diagram illustrating a specific structure of the cooling apparatus according to the exemplary embodiment. The cooling apparatus includes a cold plate 101 that is cooling unit, piping 102 through which a refrigerant such as water flows, couplers 104 connected to external piping to supply and discharge the refrigerant, and a coupler fixing block 103 for fixing the couplers 104. A flow path through which the refrigerant flows is disposed inside the cold plate 101. The cold plate 101 comes into contact with an electronic component such as a semiconductor component to absorb heat. Metal piping, for example, can be used for the piping 102.

By causing the cold plate 101 to come into contact with a semiconductor component 105, the cold plate 101 absorbs heat of the semiconductor component 105. The refrigerant flowing through the flow path in the cold plate 101 flows through a flow path constituted by the piping 102, the coupler fixing block 103, and the couplers 104. Thereby, the absorbed heat is transferred to the outside.

The coupler 104, which includes an opening/closing unit 107 inside, can supply or discharge the refrigerant to or from the flow path through the external piping when connected to the external piping. Further, the coupler 104 can confine the refrigerant in the flow path when separated from the external piping. The opening/closing unit 107 may be a mechanism incorporated in the coupler 104.

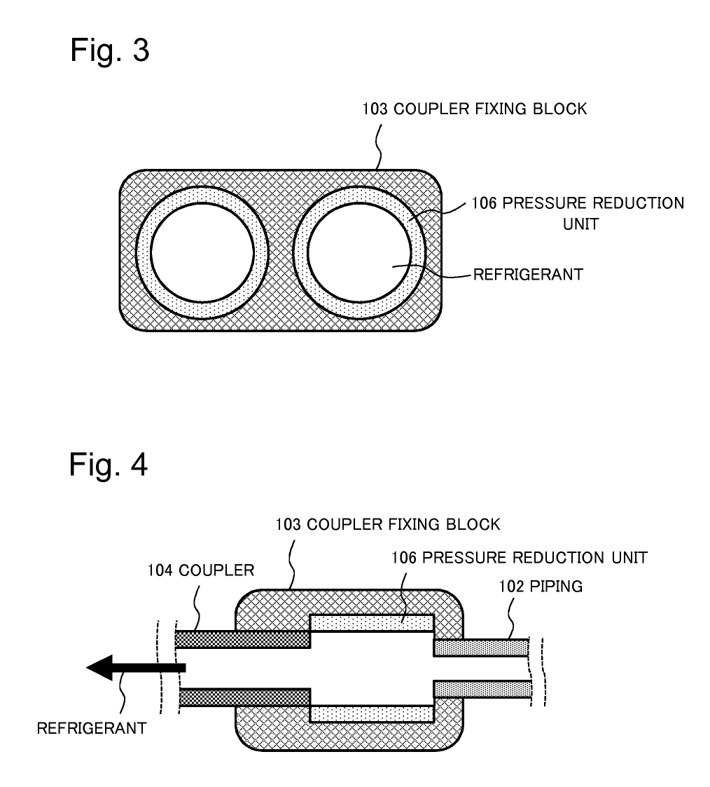

FIG. 3 is a diagram illustrating a sectional structure of the coupler fixing block 103 of the cooling apparatus according to the exemplary embodiment from the view taken along the line A-A′ in FIG. 2. FIG. 4 is a diagram illustrating a sectional structure of the coupler fixing block 103 and surroundings thereof of the cooling apparatus according to the exemplary embodiment from the vies taken along the line B-B′ in FIG. 2. As illustrated in FIGS. 3 and 4, pressure reduction unit 106 is disposed in an inner wall of the refrigerant flow path of the coupler fixing block 103. In the coupler 104 illustrated in FIG. 4, the opening/closing unit 107 is omitted.

The pressure reduction unit 106 may be formed into a sheet-shaped structure, and may contract in a thickness direction by pressure of the refrigerant. The pressure reduction unit 106 may be composed of a low-elastic soft resin layer such as silicon resin and rubber material including an independent bubble structure.

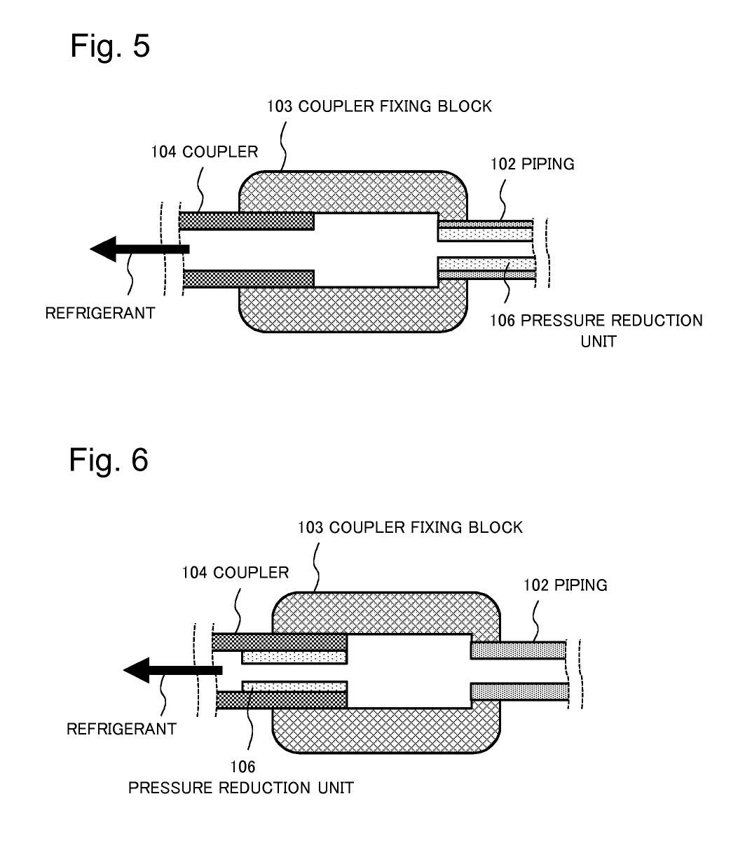

The pressure reduction unit 106 may be installed in an inner wall of the flow path of the piping 102 or in an inner wall of the flow path of the coupler 104. FIG. 5 illustrates a structure where the pressure reduction unit 106 is disposed in the inner wall of the flow path of the piping 102 in the section taken along the line B-B′ illustrated in FIG. 2. FIG. 6 illustrates a structure where the pressure reduction unit 106 is disposed in the inner wall of the flow path of the coupler 104 in the section taken along the line B-B′ illustrated in FIG. 2. In the coupler 104 illustrated in FIGS. 5 and 6, the opening/closing unit 107 is omitted.

The pressure reduction unit 106 may be installed in at least a part of the inner wall of the respective flow path of the coupler fixing block 103, the piping 102, or the coupler 104. The pressure reduction unit 106 may be fixed to the inner wall of the respective flow path of the coupler fixing block 103, the piping 102, or the coupler 104 using adhesive or the like.

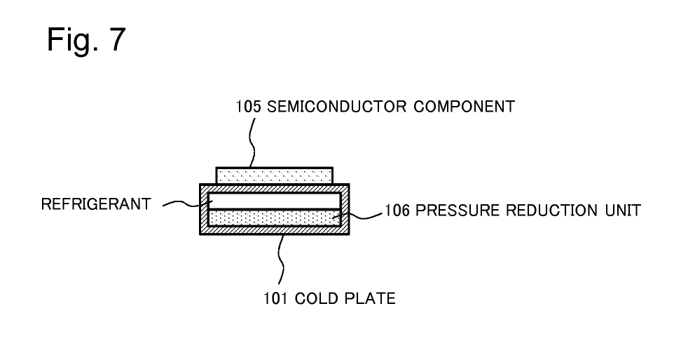

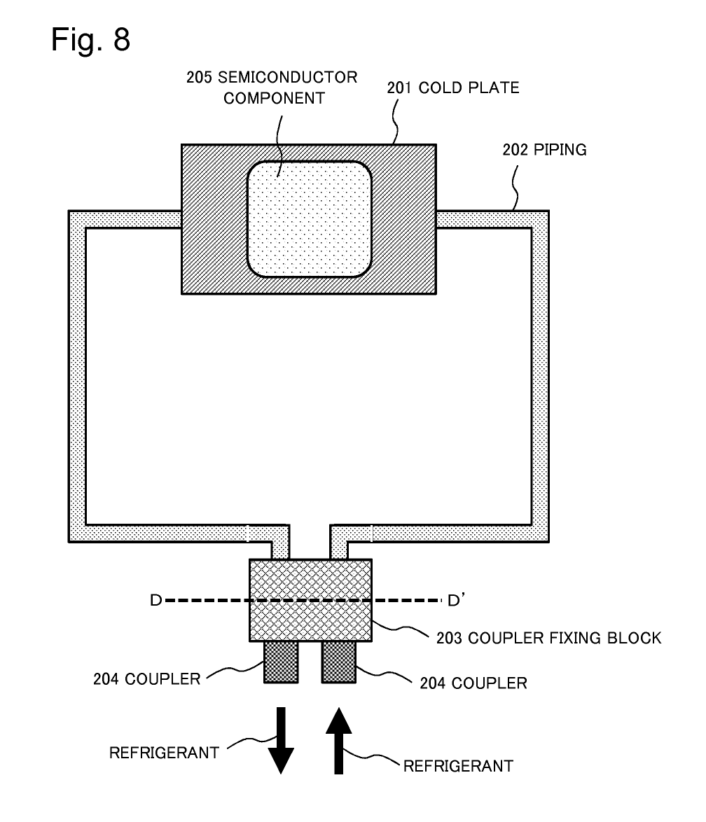

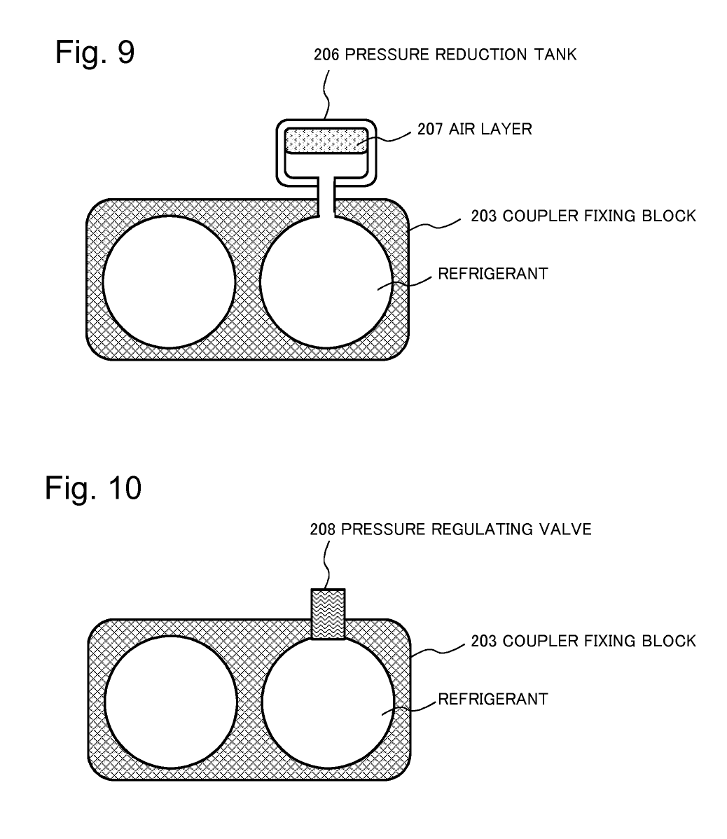

As illustrated in FIG. 7, the pressure reduction unit 106 may be installed in an inner wall of the flow path of the cold plate 101. FIG. 7 illustrates a structure where the pressure reduction unit 106 is disposed in the inner wall of the flow path of the cold plate 101 in the section taken along the line C-C′ illustrated in FIG. 2. To efficiently transmit, to the refrigerant, heat absorbed at the cold plate 101 from the semiconductor component 105, it is preferable that at least a part of the inner wall of the flow path of the cold plate 101 at a side contacting with the semiconductor component 105 directly comes into contact with the refrigerant.

When the coupler 104 is separated from the external piping, the flow path of the cooling apparatus is filled with the refrigerant by the opening/closing unit 107, and the refrigerant is confined in the flow path. In this state, when a temperature of the refrigerant increases due to an increase of an ambient temperature or the like, internal pressure increases because the refrigerant such as water is not compressed to be deformed. The increase of the internal pressure is accompanied by deformation and contraction of the pressure reduction unit 106. As a result, the pressure increase in the cooling apparatus can be reduced.

The low-elastic soft resin layer of the pressure reduction unit 106, which is made of silicon resin or rubber material including an independent bubble structure, is inexpensive. Further, operation of the pressure reduction is highly reliable because it is performed by deformation and contraction accompanying with the pressure increase.

According to the exemplary embodiment, it is possible to provide an inexpensive and highly reliable electronic component cooling apparatus that includes a pressure increase reduction function of a refrigerant such as water. The cooling apparatus according to the exemplary embodiment can be widely used for cooling not only an electronic component but also components that generate heat.

The previous description of embodiments is provided to enable a person skilled in the art to make and use the present invention. Moreover, various modifications to these exemplary embodiments will be readily apparent to those skilled in the art, and the generic principles and specific examples defined herein may be applied to other embodiments without the use of inventive faculty. Therefore, the present invention is not intended to be limited to the exemplary embodiments described herein but is to be accorded the widest scope as defined by the limitations of the claims and equivalents.

Further, it is noted that the inventor's intent is to retain all equivalents of the claimed invention even if the claims are amended during prosecution.

10 Cooling unit

11 Flow path

12 Opening/closing unit

13 Pressure reduction unit

14 External piping

101, 201 Cold plate

102, 202 Piping

103, 203 Coupler fixing block

104, 204 Coupler

105, 205 Semiconductor component

106 Pressure reduction unit

107 Opening/closing unit

206 Pressure reduction tank

207 Air layer

208 Pressure regulating valve

1. A cooling apparatus comprising:
cooling unit including a flow path through which a refrigerant flows;
opening/closing unit, included in the flow path, for confining the refrigerant; and
pressure reduction unit disposed in at least a part of an inner wall of the flow path.

2. The cooling apparatus according to claim 1, wherein the flow path is connected to or separated from external piping by a coupler, and the refrigerant is confined in the flow path when the coupler is separated from the external piping.

3. The cooling apparatus according to claim 2, wherein the flow path passes through the cooling unit, piping connected to the cooling unit, a coupler fixing block connected to the piping, and the coupler connected to the coupler fixing block.

4. The cooling apparatus according to claim 3, wherein the pressure reduction unit is disposed in the cooling unit, the piping, the coupler fixing block, or the coupler.

5. The cooling apparatus according to claim 1, wherein the pressure reduction unit includes a sheet-shaped structure.

6. The cooling apparatus according to claim 1, wherein the pressure reduction unit contracts in a thickness direction by pressure of the refrigerant.

7. The cooling apparatus according to claim 1, wherein the pressure reduction unit includes resin.

8. The cooling apparatus according to claim 1, wherein the pressure reduction unit includes silicon resin.

9. The cooling apparatus according to claim 1, wherein the pressure reduction unit includes rubber material including an independent bubble structure.

10. The cooling apparatus according to claim 1, wherein the refrigerant includes water.
